(19) United States
(12) Patent Application Publication
(10) Pub. No.: US 2016/0260828 A1
(43) Pub. Date: Sep. 8, 2016

(54) NITRIDE SEMICONDUCTOR DEVICE HAVING ALUMINUM OXIDE FILM AND A PROCESS FOR PRODUCING THE SAME

(71) Applicant: SUMITOMO ELECTRIC INDUSTRIES, LTD., Osaka (JP)

(72) Inventor: Chihoko MIZUE, Kofu-shi (JP)

(73) Assignee: SUMITOMO ELECTRIC INDUSTRIES, LTD., Osaka (JP)

(21) Appl. No.: 15/056,166

(22) Filed: Feb. 29, 2016

(30) Foreign Application Priority Data
Mar. 2, 2015 (JP) 2015-040492

(51) Int. Cl. H01L 29/778; H01L 23/31; H01L 21/02; H01L 29/205; H01L 29/66; H01L 23/29; H01L 29/20

(52) U.S. Cl. CPC H01L 29/7787; H01L 23/291; H01L 23/3171; H01L 23/293; H01L 29/2003; H01L 29/205; H01L 29/66462; H01L 21/02178; H01L 21/0228; H01L 21/02205; H01L 21/0254; H01L 21/02458

(57) ABSTRACT

A transistor primarily made of nitride semiconductor materials and a passivation film of Al₂O₃, and a process for producing the same are disclosed. The transistor, which is the type of the high-electron mobility transistor (HEMT), has a channel layer and a barrier layer sequentially grown on a semiconductor substrate. The barrier layer in a surface thereof is covered with Al₂O₃ film. A feature of the transistor of the invention is that Al₂O₃ film is formed by the atomic layer deposition (ALD) at relatively lower deposition temperature lower than 150° C., which leaves methyl groups and/or carbonyl groups in substantial concentrations measured by the Fourier transform infrared spectroscopy (FTIR).

### BACKGROUND OF THE INVENTION

1. Field of the Invention

The present application relates to a semiconductor device and a method for producing the semiconductor device,

2. Related Background

A transistor, which is primarily made of nitride semiconductor materials, having a gate insulating film, or sometimes called as a passivation film, made of aluminum oxide has been known in the field. Also, the nitride semiconductor device has been known that the current collapse inevitably appears in the pulsed current-Voltage characteristic. That is, the drain current, or the series resistance of the transistor, varies with a relatively slower time constant after an excess voltage stress such as an application of a high voltage pulse. The current collapse degrades high frequency performance of a nitride transistor.

### SUMMARY OF THE INVENTION

One aspect of the present application relates to a semiconductor device that comprises a semiconductor stack and an aluminum oxide film (Al₂O₃) film, The semiconductor stack may include, on a substrate, a channel layer and a barrier layer each made of nitride semiconductor material. The semiconductor stack provides a two dimensional electron gas (2-DEG) in an interface between the channel layer and the barrier layer. The aluminum oxide film is provided on the semiconductor stack and contains at least one of a methyl group (—CH3) and a carbonyl group (—COOH). The methyl group and the carbonyl group has a total concentration greater than 5% of a concentration of Al₂O₃, where the relative concentration of 5% is determined by a ratio of absorbance intensity of the methyl group, the carbonyl group, and the Al₂O₃ measured by a Fourier Transform Infrared Spectroscopy (FTIR).

Another aspect of the present application relates to a process to produce a semiconductor device. The process comprises steps of: (1) growing a semiconductor stack on a substrate; and (2) depositing an aluminum oxide (Al₂O₃) film on the semiconductor stack. The semiconductor stack may include a channel layer and a barrier layer made of respective nitride semiconductor materials and form a two-dimensional electron gas (2-DEG) in an interface between the channel layer and the barrier layer. A feature of the process of the present inventions is that the process of depositing the Al₂O₃ film on the semiconductor stack is carried out by an atomic layer deposition (ALD) technique as setting a deposition temperature lower than 150° C.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 schematically shows a cross section of a semiconductor device type of a field-effect transistor (FET) according to an embodiment of the present invention;

FIG. 2 shows FT-IR (Fourier Transform Infrared Reflection) spectra of aluminum oxide (Al₂O₃) films grown by an atomic layer deposition (ALD) technique at deposition temperatures of 100° C. and 300° C., respectively;

FIG. 3 shows a ratio of a dynamic current to a static current with respect to a relative concentration of the methyl group in the Al₂O₃ film;

FIG. 4 shows the FT-IR spectra of another Al₂O₃ films deposited in an oxygen plasma as an oxygen source at deposition temperatures of 100° C. and 300° C., respectively; and

FIGS. 5A to 5C show process for producing the semiconductor device shown in FIG. 1.

### DESCRIPTION OF EMBODIMENTS

Next, some embodiments according to the present application will be described as referring to drawings. In the description of the drawings, numerals or symbols same with or similar to each other will refer to elements same with or similar to each other without duplicated explanations.

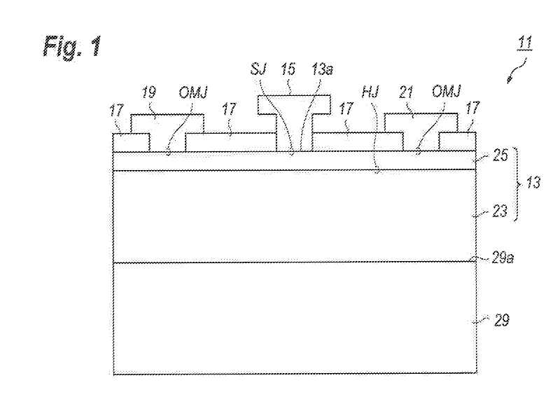

FIG. 1 schematically shows a cross section of a transistor categorized in the group III nitride semiconductor. The transistor 11, which has a type of the high electron mobility transistor (HEMT), includes a semiconductor stack 13 on a semiconductor substrate 29, a gate electrode 15, two ohmic electrodes, 19 and 21, and a passivation film 17 that protects a surface of the semiconductor stack 13 exposed between the electrodes, 15, 19, and 21. The semiconductor stack 13 includes, from the side of the semiconductor substrate 29, a channel layer 23 and a barrier layer 25 each made of nitride semiconductor materials but having compositions different from each other. The channel layer 23 forms the hetero-junction against the barrier layer 25, which locally forms a potential well in the HJ and the two-dimensional electron gas (2-DEG) is formed along the Ill. Further specifically, the channel layer 23 may be made of gallium nitride (GaN) and the HEMT 11 thus configured may be called as a GaN-HEMT. The substrate 29 may be made of silicon carbide (SiC), silicon (Si), sapphire (Al₂O₃), and/or GaN. The barrier layer 25 may be made of AlGaN, InAlN, or AlGaInN which is a composite material of the former two materials. The semiconductor stack 13 may further include a cap layer made of n-type GaN on the barrier layer 25. Still additional nitride semiconductor layer may be interposed between the substrate 29 and the semiconductor stack 13 in order to enhance the crystal quality of the semiconductor stack 13.

In the transistor thus configured, the gate electrode 15 forms a Schottky junction (SJ)against the surface 13a of the semiconductor stack 13. Two electrodes, 19 and 21, which may be a source electrode and a drain electrode, form respective ohmic contacts against the semiconductor stack 13. The passivation film 17 is in contact to the surface 13a of the semiconductor stack 13 and the sides of the gate electrode 15. The passivation film 17 may be made of aluminum oxide (Al₂O₃) with a thickness of about 40 nm and containing at least one of a methyl group (—CH₃) and/or a carbonyl group (—COOH) as impurities. Explanations below refer to a notation of I(λₐ), for instance, I(650 cm⁻¹), corresponding to an absorbance of infrared light at a wavelength of 650 cm⁻¹ of the methyl group or the carbonyl group.

### First Embodiment

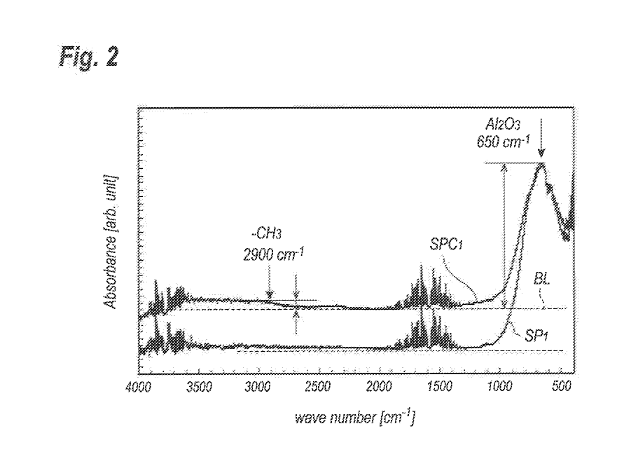

FIG. 2 show spectra, SP1 and SPC1, of the. Fourier Transform Infrared Spectroscopy (FTIR) of two aluminum oxide (Al₂O₃) films each formed by the Atomic Layer Deposition (ALD) technique. The horizontal axis corresponds to the wavelength of infrared light irradiated to Al₂O₃ film, while, the vertical axes denotes the absorbance by Al₂O₃. As shown in FIG. 2, two spectra, SP1 and SPC1, have large peaks around 650 cm⁻¹ due to the absorbance by Al₂O₃ itself, which will be called as primary peak. The specimens of Al₂O₃ film for investigating the effect on the current collapse are prepared by conditions of:

| deposition | | 100° C. to 300° C., |
|---|---|---|
| temperature | | |
| sources | O | water (H₂O), |
| | Al | Tri-Methyl-Aluminum (TMA). |

The methyl group shows a large absorbance around 2900 cm⁻¹, The intensity of the absorbance at 2900 cm⁻¹ measured from the base line BL, which is obtained by eliminating the peak around 650 cm⁻¹, may be referred as a concentration of the methyl group and denoted as [CH₃]. Comparing the spectra SPC1, which was obtained for the specimen prepared at a deposition temperature of 100° C., with the other spectra SRI obtained for another specimen deposited at a deposition temperature of 300° C.; the absorbance by the methyl group, exactly, a ratio of the absorbance by the methyl group appearing around 2900 cm⁻¹ to the absorbance by Al₂O₃ at 650 cm⁻¹, depends on the deposition temperature. The absorbance appearing as a rise from the baseline BL around 2900 cm⁻¹ is due to various reasons except for the methyl group. For instance, a thickness of Al₂O₃ film influences the absorbance by the methyl group, Accordingly, the normalization by the absorbance of Al₂O₃ appearing as a peak at 650 cm⁻¹ becomes effective for comparing the relative concentration of the methyl group left in Al₂O₃ film 17.

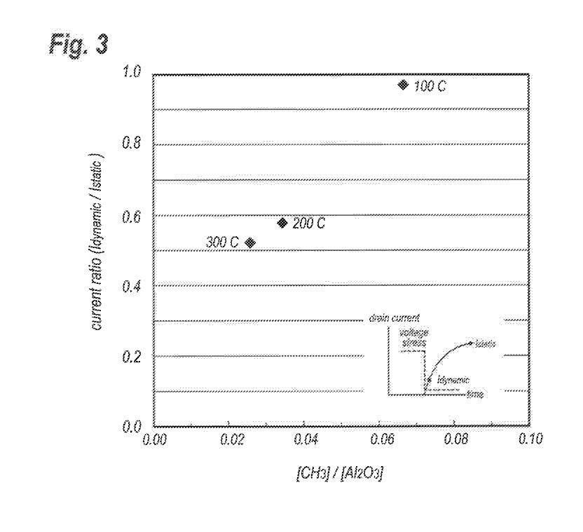

FIG. 3 shows an electrical characteristic of a transistor with the arrangement shown in FIG. 1 but the passivation films 17 thereof were formed in deposition temperatures of 100 to 300° C., respectively. The electrical characteristic is represented by a ratio of the drain current just after the excess voltage stress to that in a static condition, which is known as the current collapse. That is, the unity current collapse means that the transistor may fully follow the input signal even immediate after the excess voltage stress. Horizontal axis in FIG. 3 corresponds to the relative concentration of the methyl group measured by the ratio of the absorbance of the methyl group against that of Al₂O₃, namely [CH₃]/[Al₂O₃], as described above. The current collapse was measured by a ratio of a dynamic drain current against a static drain current. That is, the dynamic drain current was measured by procedures of:

(1) the transistor was turned on, by suppling positive biases, several volts, to the gate and the drain thereof, respectively, from a fully turned-off status supplied with the biases to the gate and drain of a deep negative bias and a large positive bias exceeding several scores of volts, sometimes reaching a hundred volt, respectively; and measures the dynamic drain current at an instant with a preset delay after the supplement of the positive biases to the gate and the drain; and
(2) the drain current was measured at another instant with an enough delay after the supplement of the positive biases, which may be called as a static current.
A ratio of the dynamic current to the static current was measured as the current collapse. Because surface states induced in the surface of the barrier layer 25 are negatively charged during the turn-off state, which becomes an obstacle for the 2-DEG in the HJ to flow smoothly along the HJ and the drain current reduces immediate after the supplement of the positive biases until the negatively charged surface states are compensated. That is, the drain current gradually increases and finally recovers the static value thereof enough after the supplement of the positive biases. Accordingly, the ratio of the dynamic drain current Idynamic to the static drain current Istatic becomes a measure of the current collapse.

Referring to FIG. 3 the specimen having Al₂O₃ film formed at the deposition temperature of 100° C. shows the higher current collapse. When the concentration of the methyl group exceeds 0.05 (5%), the transistor 1 had the current ratio greater than 0.8. The Al₂O₃ film containing the methyl group with the normalized concentration thereof greater than 0.05 determined from the FT-IR. spectrum was obtained by the deposition temperature of lower than 150° C. Specifically, the deposition temperature lower than 150° C. was preferable for obtaining Al₂O₃ film containing the normalized concentration of residual methyl group greater than 0.05. The residual concentration of the methyl group may be controlled by overlapping a period for supplying the TMA as the aluminum source with a period for supplying the water as the oxygen source.

### Second Embodiment

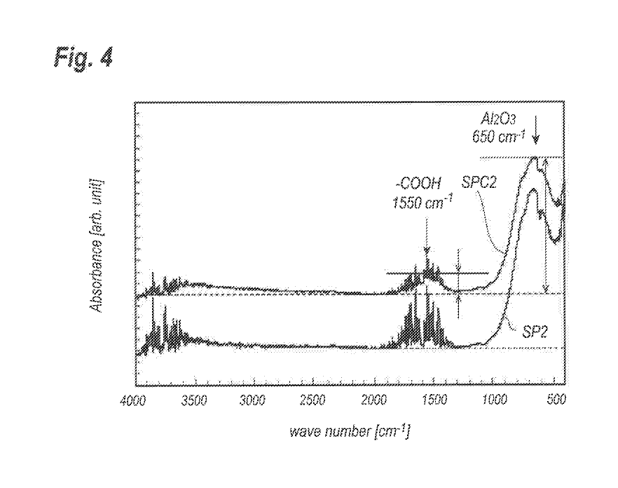

FIG. 4 shows another FT-IR spectrum for specimens of the Al₂O₃ film formed by other conditions different from the aforementioned conditions. The horizontal axis and the vertical axes in FIG. 4 correspond to the wavelength of the infrared light and the absorbance of Al₂O₃, respectively. Two spectra, SPC2 and SP2, also show a large peak around 650 cm⁻¹, which corresponds to the absorbance of Al₂O₃ itself, and, other peaks appear around 1550 cm⁻¹, which are distinguishable from the spectrum shown n FIG. 2 and correspond to the absorbance by the carbonyl group (—COOH). The specimens investigated in the second embodiment were prepared by the conditions below:

| deposition | | 100° C. to 300° C., |
|---|---|---|
| temperature | | |
| sources | O | oxygen plasma, |
| | Al | Tri-Methyl-Aluminum (TMA). |

That is, the conditions are different from those of the first embodiment only on a point that the oxygen source is replaced to the oxygen plasm from water (H₂O). The carbonyl group in the residual concentration in the Al₂O₃ film may depend on the deposition temperature.

Similar to the first embodiment, the Al₂O₃ films were thus formed for passivating the surface of the semiconductor stack 13 of the transistors 11, and the respective transistors 11 were compared by the current ratio of the dynamic current Idynamic to the static current Istatic each measured under the bias conditions same as those described in the first embodiment, As a result, a transistor 11 having the Al₂O₃ film formed under the deposition temperature of 100° C., which had the residual concentration of the carbonyl group of 0.1 normalized by the absorbance peak of the Al₂O₃ itself, showed the current collapse substantially same with those obtained for the transistor 11 having the Al₂O₃ film with the residual normalized concentration of the methyl group of 0.08; that is, the Al₂O₃ film formed under the deposition temperature below 150° C.

In semiconductor devices, in particular, a semiconductor device comprised of group III nitride semiconductor materials, unintentional deep traps are possibly induced in the interface between the surface of the semiconductor stack and the passivation film because of the quality of the passivation film, residual impurities on the semiconductor layer, dislocations induced on the surface of the semiconductor layer and so on. A process to form such semiconductor devices is often designed so as to enhance the quality of the passivation film as possible. An ALD technique usually sets the deposition temperature thereof around or higher than 300° C. to enhance the quality of the deposited from by accelerating the decomposition and desorption of the source materials. The deposition temperature of 150° C. or lower has been positively avoided. However, for the passivation film made of Al₂O₃, the methyl group and the carbonyl group are found to be substantially left in the deposited Al₂O₃ film, and to enhance the current collapse of the semiconductor device having such an Al₂O₃ film as the passivation film. The Al₂O₃ film containing the methyl group and/or carbonyl group in a substantial concentration, which has slight electrical conductivity, may not only disperse the concentration of the electric field but also compensate the deep traps of the surface stages induced in the surface of the semiconductor stack. The FT-IR technique used for investigating the electron device of the embodiments, compared with a mass-spectroscopy conventionally often used for analyzing the quality of the deposited film, may determine the relative concentration of chemical impurities such as the methyl group and/or the carbonyl group, where the relative concentration is the key factor of the present embodiments. The FT-IR for evaluating the concentration of the methyl group and/or the carbonyl group in Al₂O₃ may provide not only information of bonding statuses between atoms, namely aluminum (Al) and oxide (O) consisting Al₂O₃, and molecules, namely, the methyl group and/or the carbonyl group, but also the residual concentration of the molecules, namely the methyl group and the carbonyl group, in the deposited Al₂O₃ film.

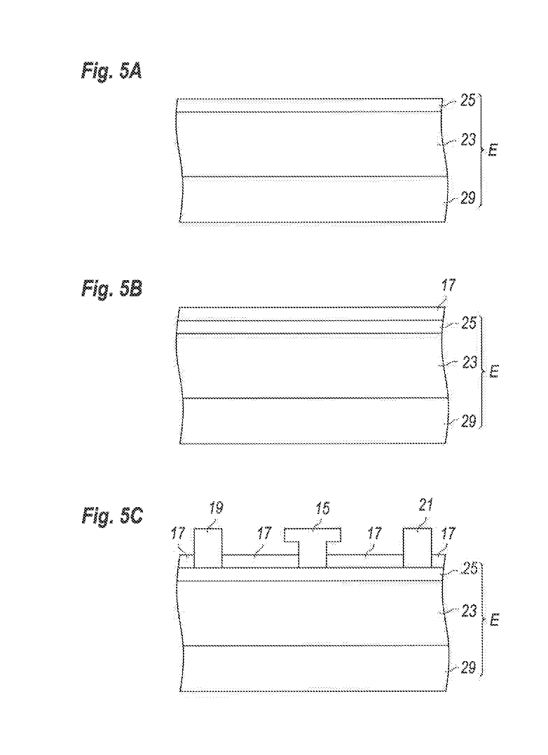

FIGS. 5A to 5C show primary processes for producing the GaN-HEMT shown in FIG. 1. Referring to FIG. 5A, the process first grows, by the molecular beam epitaxy (MBE) or the organic metal vapor phase epitaxy (OMVPE), a channel layer 23 of gallium nitride (GaN) and a barrier layer 25 of aluminum-gallium nitride AlGaN) sequentially on a semiconductor substrate 29 of silicon carbide (SiC) to prepare an epitaxial substrate E containing those layers. As described, a buffer layer may be interposed between the semiconductor substrate 29 and the channel layer 23.

Next, as shown in FIG. 5B, the process transfers the epitaxial substrate E from a furnace for the epitaxial growth to a reaction chamber of the ALD. Then, the Al₂O₃ film 17 of aluminum oxide (Al₂O₃) is deposited on the surface of the epitaxial substrate E by a thickness of, for instance, 40 nm, or the Al₂O₃ film 17 preferably has a thickness of at least a half of that of the barrier layer 25 but thinner than, for instance, 50 nm. The deposition of Al₂O₃ is carried out under the conditions of, at the deposition temperature of 100° C. as alternately supplying a source material for oxygen (O), which is the oxygen plasma, and another source material for aluminum (Al), which is the tri-methyl-aluminum (TMA) in the present embodiment, within the reaction chamber of the ALD. The combination of the oxygen plasma and the TMA is effective for increasing the concentration of the carbonyl group in the Al₂O₃ film, Another condition using water or steam as the oxygen source is effective for enhancing the concentration of the methyl group. As described above, when the deposition temperature of the Al₂O₃ film is set in those temperatures ordinarily adopted in the semiconductor process to eliminate impurities and to enhance the decomposition; the methyl group and/or the carbonyl group become hard to be left in the deposited Al₂O₃ film. Accordingly, the deposition temperature of the present embodiment is preferable to be lower than 150° C., further preferably to be lower than 100° C.

The passivation film 17 is not restricted to those aforementioned embodiments. For instance, the embodiments concentrate on the mono-Al₂O₃ film, However, the passivation film 17 may have multiple thin films. That is, the passivation film 17 may alternately stack the Al₂O₃ film of the embodiments and another Al₂O₃ film where the residual concentration of the methyl group and/or the carbonyl group thereof is smaller than that of the former Al₂O₃ film, or the passivation film 17 may alternately stack Al₂O₃ film of the embodiments and other films made of silicon oxide (SiO₂), silicon nitride (SiN), aluminum nitride (AlN), and so on. In such an arrangement, the Al₂O₃ film deposited by the present embodiments is preferable to be in direct contact to the epitaxial substrate E. When films except for the Al₂O₃ film of the embodiments is in directly contact to the epitaxial substrate E, Al₂O₃ film of the embodiments is preferably to be formed within a range of 1 μm from the surface of the epitaxial substrate E.

After the deposition of the passivation film 17, the electrodes of the source, the gate, and the drain, 19, 15, and 17, are formed on the epitaxial substrate E. Specifically, the process forms an opening in the passivation film 17 at a position for the gate; then, the gate electrode 15 is formed by, for instance, the metal lift-off technique. Subsequently, the process also forms other openings in the passivation film 17 at positions corresponding to the source 19 and the drain 21 in respective sides of the gate electrode 15. The ohmic metal for the source 19 and the drain 21 are formed to fill the respective openings. One of the key features of the semiconductor device 11 of the present invention is that the gate electrode 15 is in contact to, not only the surface of the epitaxial substrate E, but the sides of the opening prepared for the gate electrode. That is, the opening formed in the passivation film for the gate electrode 15 fully fills the opening and substantially no surface of the semiconductor stack E may be exposed between the gate electrode 15 and the passivation film 17. Thus, the process produces the transistor, the GaN-HEMT, shown in FIG. 1.

The present invention, by leaving the methyl group and/or the carbonyl group, in the deposited Al₂O₃ film, may compensate the surface states induced in the surface of the interface between the semiconductor layer and the Al₂O₃ film. In other words, the methyl group and/or the carbonyl group left in the deposited Al₂O₃ film may effectively or substantially extract electrons captured in the surface states, which suppresses the surface of the semiconductor layer from being negatively charged and the 2-DEG in the channel layer from being affected from the negatively charged surface. Thus, the transistor having the passivation film 17 substantially left with the methyl groups and/or the carbonyl groups may effectively suppress the current collapse.

While there has been illustrated and described what are presently considered to be example embodiments of the present invention, it will be understood by those skilled in the art that various other modifications may be made, and equivalents may be substituted, without departing from the true scope of the invention. Additionally, many modifications may be made to adapt a particular situation to the teachings of the present invention without departing from the central inventive concept described herein. Therefore, it is intended that the present invention not be limited to the particular embodiments disclosed, but that the invention include all embodiments falling within the scope of the appended claims.

1. A semiconductor device, comprising:
a semiconductor stack including, on a substrate, a channel layer made of nitride semiconductor material and a barrier layer made of nitride semiconductor material, the semiconductor stack providing a two dimensional electron gas (2-DEG) in an interface between the channel layer and the barrier layer; and
an aluminum oxide (Al₂O₃) film provided on the semiconductor stack, the aluminum oxide film containing at least one of a methyl group (—CH₃) and a carbonyl group (—COOH) with a total concentration greater than 5% of a concentration of Al₂O₃ determined by a ratio of absorbance intensity of the methyl group, the carbonyl group, and the Al₂O₃ measured by a Fourier Transform Infrared Spectroscopy (FTIR).

2. The semiconductor device of claim 1, wherein the absorbance intensity of the methyl group, the carbonyl group, and the Al₂O₃ correspond to the absorbance intensity measured at 2900 cm⁻¹, 1550 cm⁻¹ and 650 cm⁻¹, respectively.

3. The semiconductor device of claim 1, wherein the Al₂O₃ film substantially contains only the methyl group.

4. The semiconductor device of claim 1, wherein the Al₂O₃ film substantially contains only the carbonyl group.

5. The semiconductor device of claim 1, wherein the substrate is one of silicon carbide (SiC), sapphire, silicon (Si), and gallium nitride (GaN), and the channel layer is gallium nitride (GaN).

6. The semiconductor device of claim 1, wherein the barrier layer includes at least one of aluminum-gallium nitride (AlGaN), indium-aluminum nitride (InAlN), and aluminum-gallium-indium nitride (AlGaInN).

7. The semiconductor device of claim 1, wherein the Al₂O₃ film has a thickness of at least a half of a thickness of the barrier layer but thinner than 50 nm.

8. A process for producing a nitride semiconductor device, comprising steps of:
growing a semiconductor stack on a substrate, the semiconductor stack including a channel layer and a barrier layer from a side of the substrate, the channel layer and the harrier layer forming a two-dimensional electron gas (2-DEG) in an interface therebetween; and
depositing an aluminum oxide (Al₂O₃) film on the semiconductor stack by an atomic layer deposition (ALD) technique as setting a deposition temperature lower than 150° C.

9. The process of claim 8, wherein the step of depositing the Al₂O₃ film includes a step of depositing the Al₂O₃ film by the ALD technique at a temperature lower than 100° C.

10. The process of claim 8, wherein the step of depositing the Al₂O₃ film includes a step of supplying a tri-methyl-aluminum (TMA) as an aluminum (Al) source and water (H₂O) as an oxygen (O) source.

11. The process of claim 8, wherein the step of depositing the Al₂O₃ film includes a step of supplying a tri-methyl-aluminum (TMA) as an aluminum (Al) source as exposing the semiconductor stack in an oxygen plasma as an oxygen (O) source.

12. The process of claim 8, further including a step of growing a buffer layer before the step of growing the semiconductor stack.

13. The process of claim 8, further includes a step of growing a cap layer directly on the semiconductor stack, wherein the step of depositing the Al₂O₃ film includes a step of depositing the Al₂O₃ film on the cap layer at the deposition temperature lower than 150° C.

14. The process of claim 8, wherein the step of growing the semiconductor stack includes steps of growing a gallium nitride (GaN) as the channel layer and growing at least one of aluminum-gallium nitride (AlGaN), indium-aluminum nitride (InAlN), and aluminum-gallium-indium nitride (AlGaInN) as the barrier layer.

15. The process of claim 8, wherein the step of depositing the Al₂O₃ film includes a step of depositing the Al₂O₃ film by a thickness of at least a half of a thickness of the barrier layer but thinner than 50 nm.
